(19) United States
(12) Patent Application Publication
(10) Pub. No.: US 2002/0180316 A1
(43) Pub. Date: Dec. 5, 2002

(54) Piezoelectric ultrasonic transducer comprising a housing and an insulating layer

(76) Inventor: Klaus Van Der Linden, Redwitz-Unterlangenstadt (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 10/174,058

(22) Filed: Jun. 17, 2002

Related U.S. Application Data
(63) Continuation of application No. PCT/DE00/04455, filed on Dec. 14, 2000.

(30) Foreign Application Priority Data
Dec. 17, 1999 (DE) 199 61 095.9

(51) Int. Cl. H01L 41/053

(52) U.S. Cl. 310/348

(57) ABSTRACT

The piezoelectric ultrasonic transducer has a housing and a piezoelectrically active layer which is connected to the housing via an insulating layer. An adaptive layer is additionally located between the insulation layer and the housing. The coefficient of thermal expansion of the adaptive layer has a value between the values of the coefficients of thermal expansion of the housing and the insulating layer. An ultrasonic transformer of this type has a long service life even when it is used in an environment of frequent temperature fluctuations.

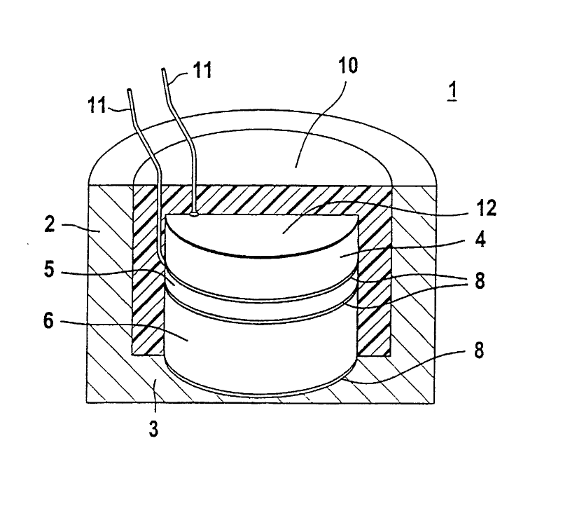

### CROSS-REFERENCE TO RELATED APPLICATION

This application is a continuation of copending International Application No. PCT/DE00/04455, filed Dec. 14, 2000, which designated the United States and which was not published in English.

### BACKGROUND OF THE INVENTION

### Field of the Invention

The invention relates to a piezoelectric ultrasonic transducer comprising a housing and a piezoelectrically active layer that is connected to the housing via an insulating layer.

Such an ultrasonic transducer is suitable both for transmitting and for receiving ultrasound. It can be used in gases and in liquids. Such an ultrasonic transducer is used, for example, in a flow counter for determining the flow rate of a gas or a liquid. Furthermore, such an ultrasonic transducer can be used to determine the liquid level in a container by means of a travel time measurement of ultrasonic pulses.

For operating purposes, the piezoelectrically active layer is excited to emit an ultrasonic pulse, mostly with the aid of voltage pulses. Conversely, the detection of an ultrasonic pulse is performed via a voltage signal that the piezoelectrically active layer outputs. The piezoelectrically active layer is installed in a suitable housing for the purpose of particularly effective emission of ultrasound in one direction without large signal loss.

There are strict standards regarding the electrical insulation of the current-carrying or energized assemblies for applications in explosive gases or liquids. For this reason; there is arranged an insulating layer between the housing and the piezoelectrically active layer provided with electric terminals.

The layer components of the ultrasonic transducer are usually permanently connected to one another and to the housing via an adhesive. In many cases, for example in the case of use in aggressive or corroding gases or liquids, the layers and the housing can, however, not be constructed from materials of identical thermal expansion coefficients. In the case of use in certain chemicals, specific materials are even prescribed for reasons of safety. In the case of temperature changes this leads to the fact that different thermal expansions cause stresses in the composite system that can be expressed externally by bending. These mechanical stresses are a static continuous load that acts as a function of temperature and damages the composite system in the long run.

Ultrasonic transducers for solving this problem are known wherein the individual layers and the housing are connected to one another via highly elastic adhesive or thick adhesive layers. However, it is a disadvantage that highly elastic adhesives and thick adhesive layers lead to a high damping of the transmitted ultrasonic signal.

### SUMMARY OF THE INVENTION

It is accordingly an object of the invention to provide an piezoelectric ultrasonic transducer with a housing and an insulating layer, which overcomes the above-mentioned disadvantages of the heretofore-known devices and methods of this general type and exhibits a long service life even if it is subjected to an environment with frequent temperature changes.

With the foregoing and other objects in view there is provided, in accordance with the invention, a piezoelectric ultrasonic transducer, comprising:

a housing;

a piezoelectrically active layer in the housing;

an insulating layer connecting the piezoelectrically active layer to the housing;

an adaptive layer disposed between the insulating layer and the housing, the adaptive layer having a thermal expansion coefficient with a value between a value of an expansion coefficient of the housing and a value of an expansion coefficient of the insulating layer.

In other words, the objects of the invention are achieved for a piezoelectric ultrasonic transducer of the type mentioned above by virtue of the fact that there is arranged additionally between the insulating layer and housing an adaptive layer whose thermal expansion coefficient has a value between the values of the expansion coefficients of the housing and the insulating layer.

In this way it is possible to reduce the mechanical stresses occurring in the layer system or composite system of the ultrasonic transducer in the case of temperature fluctuations and of different thermal expansion coefficients of the individual materials, but without damping the outputted ultrasonic signal. Furthermore, it is possible in this way even for materials with very different thermal expansion coefficients to be bonded to one another in conventional fashion without a loss in efficiency of the ultrasonic transducer owing to thick and/or soft, highly elastic adhesives in the case of designs in accordance with the prior art. High numbers of temperature changes without damage to the ultrasonic transducer are possible owing to the low mechanical stresses. Temperature changes act as a dynamic load. The peak stresses occurring in the case of a dynamic load are low.

In an advantageous refinement of the invention, the housing is a metal housing. The sound can advantageously be coupled into liquids in this way.

Particularly for use in aggressive liquids or gases or generally in a corroding environment, it is, furthermore, advantageous when the housing consists of a steel, in particular of a stainless steel.

Although, of course, any material that exhibits the piezoelectric effect suitable for the piezoelectrically active layer, it is nevertheless advantageous for technical applications when the piezoelectrically active layer consists of a piezoceramic. Applying a homogeneous electric field generates in the piezoceramic a polar axis that is required for the occurrence of the piezoelectric effect. Because of its composition, a piezoceramic permits adaptation to different requirements. A suitable piezoceramic is, however, a so-called PZT ceramic, which stands for a lead zirconate titanate oxide ceramic.

In accordance with a further advantageous refinement of the invention, the insulating layer consists of a ceramic, in particular of an aluminium oxide ceramic. Such ceramics exhibit good mechanical properties in conjunction with high insulating ability. In particular, an aluminium oxide ceramic is distinguished by a similar thermal expansion coefficient to that of a lead zirconate titanate oxide ceramic.

It is further advantageous, in particular in the case of a metal housing made from steel, when the adaptive layer consists of titanium, or of a steel of material number 1.4021, 1.4460 or 1.4462. The thermal expansion coefficients of these materials are all, at 8·10⁻⁶/K to 12·20⁻⁶/K, between the thermal expansion coefficient of aluminium oxide ceramic of 7·10⁻⁶/K and the thermal expansion coefficient of steel of material number 1.4571 for the housing of 17·10⁻⁶/K. The material numbers are taken in this case from “Stahlschlüissel” [“Key to steel”], Verlag Stahlschlüssel Wegst GmbH, 18^{th} edition, 1998, Marbach. The associated compositions are to be found there.

The layer system of the ultrasonic transducer can be connected to one another in a particularly favorable and simple way when the layers are bonded to one another and the adaptive layer is bonded to the housing by means of an epoxy resin.

Other features which are considered as characteristic for the invention are set forth in the appended claims.

Although the invention is illustrated and described herein as embodied in a piezoelectric ultrasonic transducer comprising a housing and an insulating layer, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawing.

### BRIEF DESCRIPTION OF THE DRAWING

The figure is a partly sectional, perspective view of an ultrasonic transducer assembly according to the invention.

### DESCRIPTION OF THE PREFERRED EMBODIMENTS

Referring now to the sole figure of the drawing in detail, there is shown an ultrasonic transducer 1 with a housing 2 and a layer system arranged therein. The ultrasonic transducer 1 emits ultrasonic signals in the direction of the housing floor 3 and/or detects ultrasonic signals coming from this direction. The ultrasonic transducer 1 itself is of rotationally symmetrical design.

The layer system of the ultrasonic transducer 1 comprises a piezoelectrically active layer 4 made from a lead zirconate titanate oxide ceramic, an insulating layer 5 made from an aluminium oxide ceramic, and an adaptive layer 6 made from titanium. The piezoelectrically active layer 4, the insulating layer 5 and the adaptive layer 6 are permanently connected to one another in each case via adhesive layers 8 made from epoxy resin. The adaptive layer 6 is bonded to the housing floor 3 via a further epoxy resin adhesive layer 8.

The exemplary ultrasonic transducer 1 illustrated in the figure has a diameter of 30 mm. The adhesive layers 8 are approximately 5 μm thick. The thickness of the piezoelectrically active layer 4 is approximately 1 mm. The insulating layer 5 has a thickness of approximately 1/10 mm. The adaptive layer is approximately 2 mm thick.

The housing 2 consists of a stainless steel with the material number 1.4571.

The layer system of the ultrasonic transducer 1 is passed into the housing 2 via an insulating material 10. Epoxy resin is used as insulating material 10.

Electric terminals 11 are provided for driving the ultrasonic transducer 1. Electric terminals 11 are connected to a flat electrode—not evident in the drawing—on the surface of the insulating layer and consisting of sputtered—on gold, or to the electrode 12 applied in a planar fashion to the top side of the piezoelectrically active layer 4. In this case, the electrode 12 comprises a sputtered layer consisting of the metals Cr/Pt/Au.

To operate the ultrasonic transducer, it is supplied with voltage pulses. Suitable circuits for this are prior art. Again, incoming ultrasonic signals can easily be detected with the aid of the ultrasonic transducer 1 illustrated via the voltage values output by the piezoelectrically active layer 4.

The ultrasonic transducer 1 illustrated is suitable, in particular, for use in aggressive or potentially explosive gases and liquids, where it is additionally exposed to frequent temperature changes. Such an application is, for example, the use of the ultrasonic transducer 1 in flow counters.

I claim:

1. A piezoelectric ultrasonic transducer, comprising:
a housing;
a piezoelectrically active layer in said housing;
an insulating layer connecting said piezoelectrically active layer to said housing;
an adaptive layer disposed between said insulating layer and said housing, said adaptive layer having a thermal expansion coefficient with a value between a value of an expansion coefficient of said housing and a value of an expansion coefficient of said insulating layer.

2. The piezoelectric ultrasonic transducer according to claim 1, wherein said housing is a metal housing.

3. The piezoelectric ultrasonic transducer according to claim 1, wherein said housing is a steel housing.

4. The piezoelectric ultrasonic transducer according to claim 3, wherein said housing consists of stainless steel.

5. The piezoelectric ultrasonic transducer according to claim 1, wherein said piezoelectrically active layer is a piezoceramic layer.

6. The piezoelectric ultrasonic transducer according to claim 1, wherein said insulating layer is a ceramic layer.

7. The piezoelectric ultrasonic transducer according to claim 1, wherein said insulating layer consists of aluminium oxide ceramic.

8. The piezoelectric ultrasonic transducer according to claim 1, wherein said adaptive layer is a titanium or a steel selected from the group of material numbers consisting of 1.4021, 1.4460, and 1.4462.

9. The piezoelectric ultrasonic transducer according to claim 1, which comprises epoxy resin bonding said piezoelectrically active layer to said insulating layer, bonding said insulating layer to said adaptive layer, and bonding said adaptive layer to said housing.
